(19) United States
(12) Patent Application Publication
(10) Pub. No.: US 2025/0314490 A1
(43) Pub. Date: Oct. 9, 2025

(54) STRUCTURE FOR DETECTING POSITIONS OF DOOR PANEL ON SERVER, SERVER, AND COMPUTING SYSTEM

(71) Applicant: Fulian Precision Electronics (Tianjin) Co., LTD., Tianjin (CN)

(72) Inventor: JIA-FENG LIN, New Taipei (TW)

(21) Appl. No.: 18/963,629

(22) Filed: Nov. 28, 2024

(30) Foreign Application Priority Data
Apr. 3, 2024 (CN) 202410401653.4

(51) Int. Cl. G01B 21/22; H05K 7/14; H05K 7/16

(52) U.S. Cl. CPC G01B 21/22; H05K 7/1488; H05K 7/16

(57) ABSTRACT

A structure for detecting positions of a door panel on a server comprises a base board, a moving piece, a bracket, a link rod, and a detector. The moving piece moves between a first position and a second position. The bracket rotates between a first angle and a second angle. The link rod connects the bracket and the moving piece. The bracket rotates with the door panel to move the moving piece by the link rod, when the door panel is closed, the bracket is rotated to the first angle, the moving piece is moved to the first position, and the detector sends a first signal; when the door panel is opened, the bracket is rotated to the second angle, the moving piece is moved to the second position, and the detector sends a second signal. A server and a computing system with the structure are also disclosed.

### FIELD

The disclosure herein generally relates to information computing systems, and more particularly relates to a structure for detecting positions of a door panel on a server, a server, and a computing system.

### BACKGROUND

A server in the rack usually has an opening, and a hard disk is received in the server through the opening. A door panel is installed to the server to open or cover the opening. However, whether the door panel covers the opening cannot be determined. Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is an isometric view of an embodiment of a server comprising a chassis, a door panel, and a structure for detecting the door panel according to the present disclosure, showing the door panel is disassembled from the chassis.

FIG. 2 is an isometric view of the structure shown in FIG. 1, showing the structure in a condition when the door panel is closed.

FIG. 3 is an isometric view from another side of the structure shown in FIG. 2.

FIG. 4 is an enlarged view of an area IV of the structure shown in FIG. 3.

FIG. 5 is similar to FIG. 4, but showing a part of the structure, a first screw and a base board of the structure being disassembled.

FIG. 6 is an isometric view of the structure shown in FIG. 1, showing the structure in a condition when the door panel is opened.

FIG. 7 is an isometric view from another side of a part of the structure shown in FIG. 6.

FIG. 8 is an enlarged view of an area VIII of the structure shown in FIG. 3.

FIG. 9 is a cutaway, cross-sectional view of a detector and a moving piece of the structure shown in FIG. 2.

FIG. 10 is an isometric view of an embodiment of a computing system according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

The server in the rack usually has an opening for the hard disk to enter and exit, and a door panel is set at the opening. When the door panel is opened, the hard disk can be inserted into the server, and then the door panel should be reset to cover the opening to protect the server. The server may detect whether the door panel is reset, and the server runs the hard disk after the door panel is reset, but due to the limited space of the server, the structure for detecting the door panel nowadays is complicated and occupies a large space in the server. The goal of the present disclosure is to solve this problem.

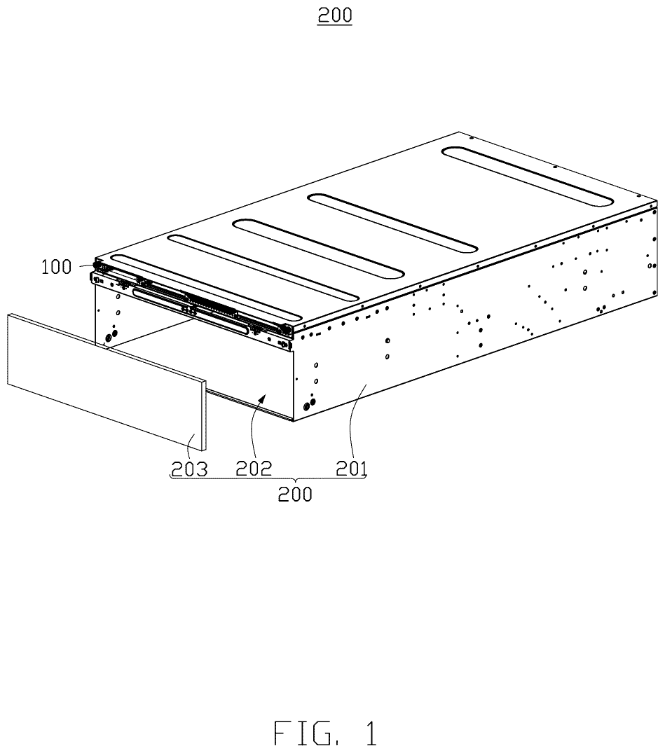

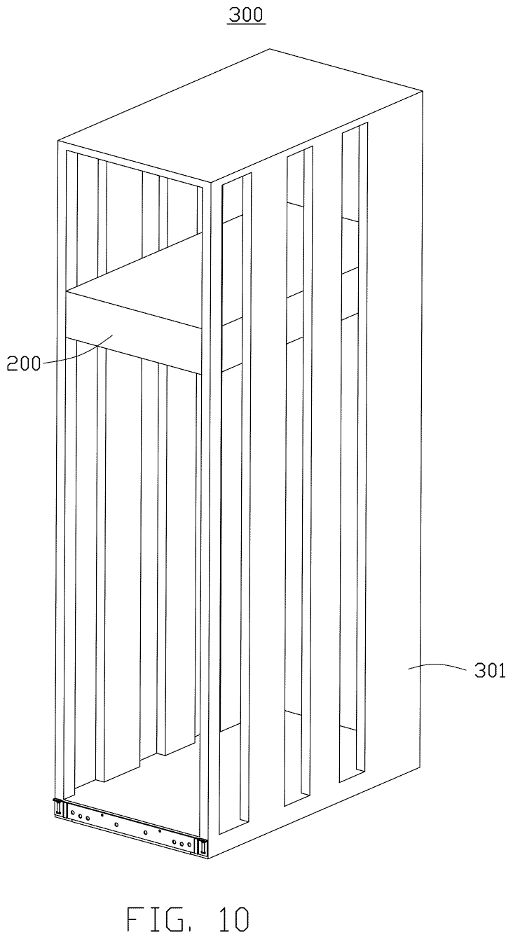

As shown in FIG. 1 and FIG. 10, a computing system 300 in an embodiment includes a rack 301 and a plurality of servers 200, the plurality of servers 200 are arranged in the rack 301 in layers, and the computing system 300 in FIG. 1 only shows one server 200 for an example. The server 200 is used to accommodate an electronic component, such as a hard disk, an expansion card, or a processor, the following embodiments take the hard disk as an example. The server 200 includes a chassis 201, a door panel 203, and a structure 100 for detecting positions of the door panel 203. The structure 100 is rotatably installed on the chassis 201. The chassis 201 has an opening 202, and the hard disk enters or exits the chassis 201 through the opening 202. The door panel 203 is used to open or close the opening 202. When users lift the door panel 203 to open the opening 202, the users can then insert the hard disk into the server 200, and then the door panel 203 needs to be reset to cover the opening 202 to protect the server 200. The structure 100 is used to detect whether the door panel 203 is reset, and only when the door panel 203 is reset (the door panel 203 closes the opening 202), the server 200 runs the hard disk.

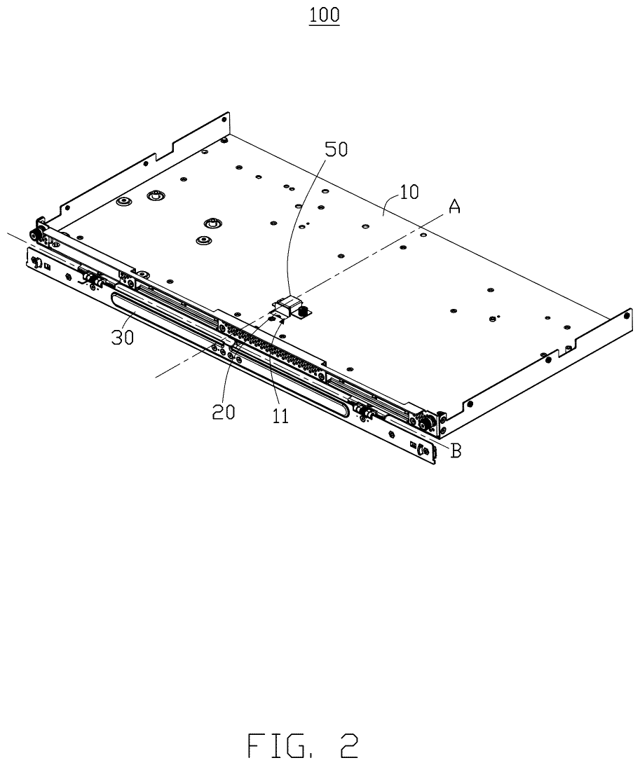

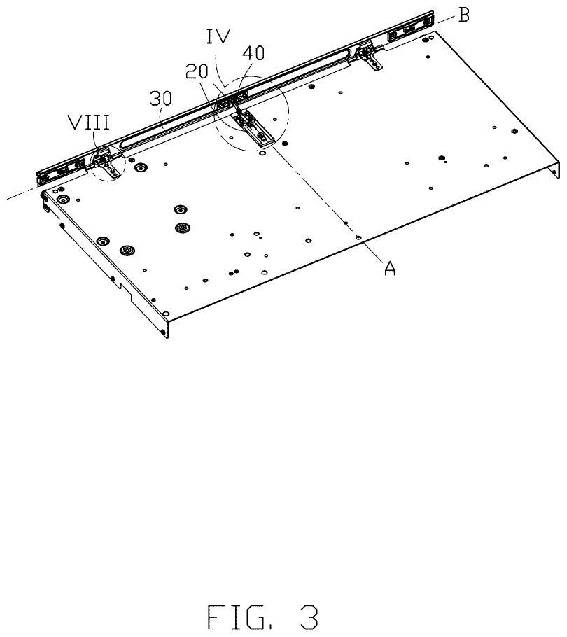

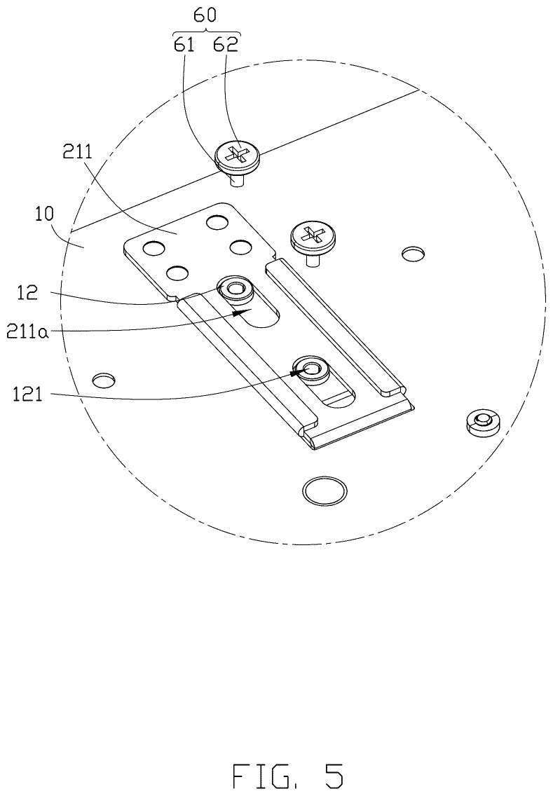

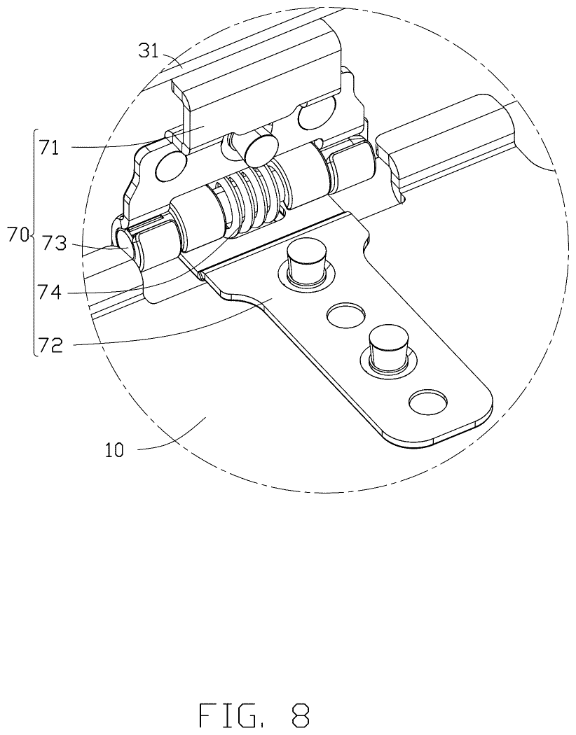

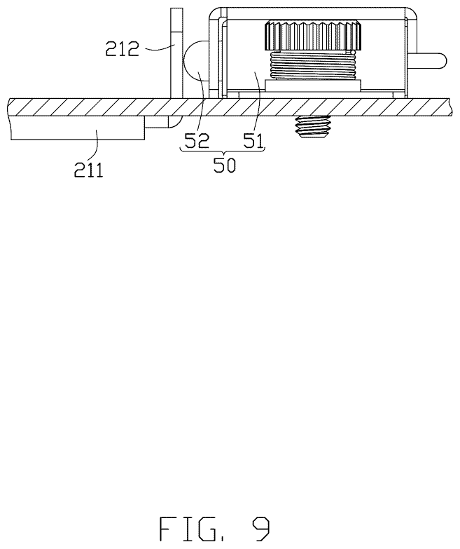

As shown in FIG. 2 to FIG. 9, in some embodiments, the structure 100 includes a base board 10, a moving piece 20, a bracket 30, a link rod 40, and a detector 50. The base board 10 is a portion of the chassis 201, such as a top board of the chassis 201. The moving piece 20 is located on the base board 10 and is movable along a line A between a first position and a second position, the line A is parallel to the base board 10. The bracket 30 is located on the base board 10 and is rotatable around an axis B between a first angle and a second angle, the axis B is parallel to the base board 10 and perpendicular to the line A. The link rod 40 connects the bracket 30 and the moving piece 20. The door panel 203 is installed on the bracket 30, the bracket 30 rotates with the door panel 203, and the bracket 30 moves the moving piece 20 by the link rod 40, which means when the bracket 30 rotates, the bracket 30 moves the moving piece 20 along the line A by the link rod 40. The detector 50 is position on the base board 10. Specifically, when the bracket 30 is at the first angle, the bracket 30 and the door panel 203 are vertical, and when the bracket 30 is at the second angle, the bracket 30 and the door panel 203 are horizontal.

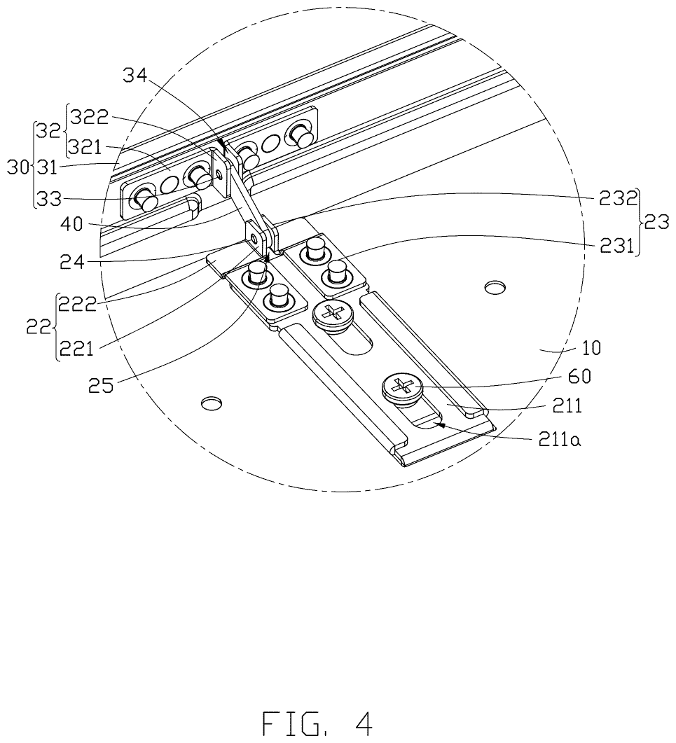

When users drop down the door panel 203 to close the opening 202, the bracket 30 rotates to the first angle, and meanwhile the bracket 30 moves the moving piece 20 moves to the first position by the link rod 40, the moving piece 20 on the first position can trigger the detector 50 to send a first signal, the first signal presents that the door panel 203 is reset and the opening 202 is closed, as shown in FIG. 2 and FIG. 4, so the server 200 can run the hard disk.

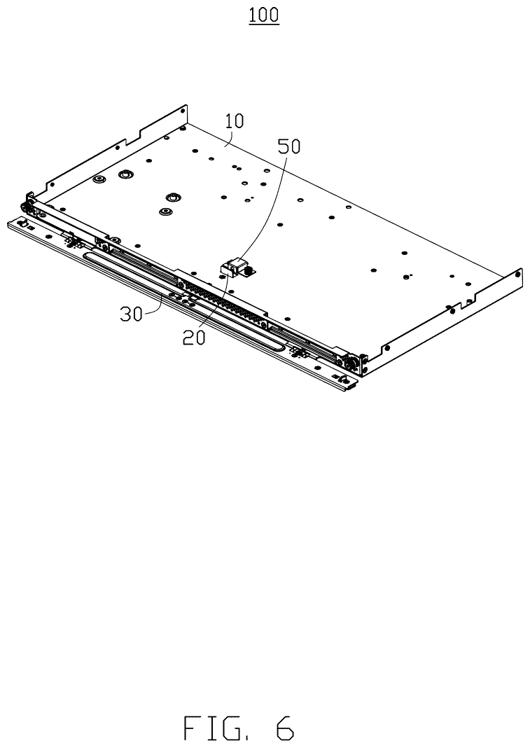

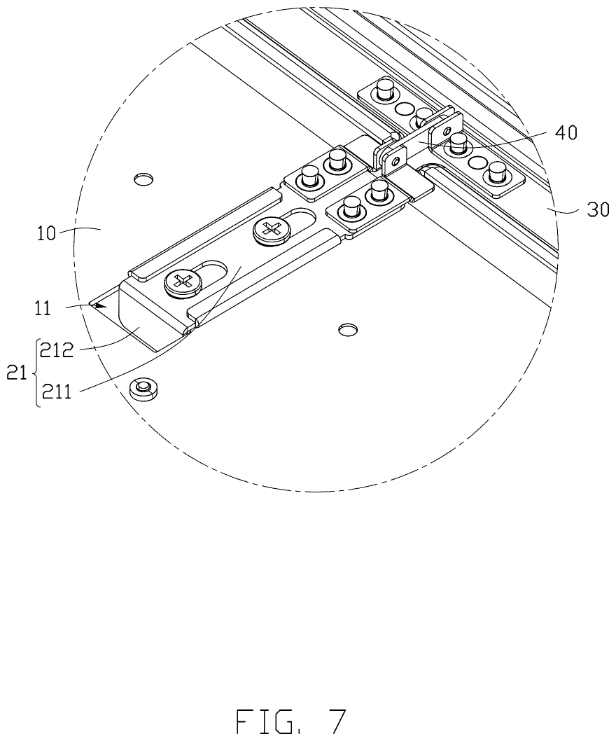

When users lift the door panel 203 to open the opening 202, the bracket 30 rotates to the second angle, and meanwhile the bracket 30 moves the moving piece 20 moves to the second position from the first position by the link rod 40, the moving piece 20 absent from the first position can trigger the detector 50 to send a second signal, the second signal presents that the door panel 203 is not reset and the opening 202 is not closes, as shown in FIG. 6 and FIG. 7, so the server 200 stops running the hard disk.

In some embodiments, the moving piece 20 includes a first assembled sheet 21, the first assembled sheet 21 includes a main board 211 and a bended board 212, the main board 211 is parallelly attached to the base board 10, the bended board 212 is perpendicular to the main board 211, the bended board 212 is between the main board 211 and the detector 50. The main board 211 and the detector 50 are on two opposite sides of the base board 10, respectively. The base board 10 has a sliding slot 11, the bended board 212 extends through the sliding slot 11 and the bended board 212 is used to trigger the detector 50 to send the first signal and the second signal, which can simplify structure of the moving piece 20 and reduce a space occupied by the moving piece 20. In some embodiments, the base board 10 has two limiting protrusions 12, the

two limiting protrusions 12 are arranged along the line A. The main board 211 has two grooves 211a, a length of the two groove 211a is along the line A, each limiting protrusion 12 is inserted in each groove 211a, a width of each groove 211a is equal to a width of each limiting protrusion 12, each groove 211a can limit each limiting protrusion 12 to move along the line A, so the main board 211 moves along the line A.

In some embodiments, each limiting protrusion 12 has a threaded hole 121, the structure 100 further includes two first screws 60, each first screw 60 includes a threaded portion 61 and a screw head 62, each threaded portion 61 is inserted into a threaded hole 121 of each limiting protrusion 12, a width of each screw head 62 is larger than a width of the each groove 211a, a distance between each screw head 62 and the base board 10 is equal to a thickness of the main board 211, so the main board 211 is attached to the base board 10.

In some embodiments, the moving piece 20 further includes a second assembled sheet 22, a third assembled sheet 23, and a first shaft 24. The second assembled sheet 22 and the third assembled sheet 23 are symmetrical to each other. The second assembled sheet 22 includes a first board 221 and a second board 222, and the first board 221 is perpendicular to the second board 222. The third assembled sheet 23 includes a third board 231 and a fourth board 232, and the third board 231 is perpendicular to the fourth board 232. The first board 221 and the third board 231 are located on the main board 211, the second board 222 and the fourth board 232 are perpendicular to the base board 10. There is a first gap 25 between the second board 222 and the fourth board 232, an end of the link rod 40 is in the first gap 25. The first shaft 24 extends through the second board 222, the link rod 40, and the fourth board 233, so the link rod 40 can rotate around the first shaft 24

In some embodiments, the bracket 30 includes a flipping board 31, two fourth assembled sheets 32, and a second shaft 33. The flipping board 31 is located on the base board 10 and is rotatable around the axis B. The two fourth assembled sheets 32 are symmetrical to each other, and each fourth assembled sheet 32 includes a fifth board 321 and a sixth board 322, the fifth board 321 is perpendicular to the sixth board 322, the fifth board 321 is located on the flipping board 31. There is a second gap 34 between the two sixth boards 322 of the two fourth assembled sheets 32, and an end of the link rod 40 away from the first gap 25 is in the second gap 34. The second shaft 33 extends through the two sixth boards 322 and the link rod 40, so the link rod 40 can rotate around the second shaft 33.

In some embodiments, the structure 100 further includes a reset component 70. The reset component 70 includes a first reset sheet 71, a second reset sheet 72, a reset shaft 73, and a spring 74. The first reset sheet 71 is located on the bracket 30, the second reset sheet 72 is located on the base board 10, the reset shaft 73 and the axis B are coincided. The first reset sheet 71 and the second reset sheet 72 rotate around the reset shaft 73. The spring 74 surrounds around the reset shaft 73, and the spring 74 is against the first reset sheet 71 and the second reset sheet 72, so to push the bracket 30 (and the door panel 203) to rotate to the first angle automatically and to keep the bracket 30 (and the door panel 203) stay at the first angle when the users drop down the door panel 203.

In some embodiments, the detector 50 includes a shell 51 and a trigger 52. The trigger 52 extends out of the shell 51, and the trigger 52 is movable relative to the shell 51 along the line A. When the moving piece 20 moves to the first position from the second position, the bended board 212 of the moving piece 20 pushes the trigger 52 towards the shell 51, to retract the trigger 52 into the shell 51, and after the moving piece 20 is on the first position, the trigger 52 triggers the first signal. When the moving piece 20 moves to the second position from the first position, the trigger 52 sticks out of the shell 51 by a spring in the shell 51 for example, and when the moving piece 20 is absent from the first position, the trigger 52 triggers second signal.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A structure configured for detecting positions of a door panel on a server, the structure comprising:
a base board;
a moving piece movable along a line between a first position and a second position on the base board;
a bracket rotatable around an axis between a first angle and a second angle on the base board, the axis substantially perpendicular to the line, and the bracket configured for supporting a door panel;
a link rod connected to the bracket and the moving piece; and
a detector positioned on the base board,
wherein when the door panel is rotated, the bracket rotates with the door panel and moves the moving piece by the link rod, when the door panel is closed, the bracket is rotated to the first angle, the moving piece is moved to the first position, and the detector sends a first signal; when the door panel is opened, the bracket is rotated to the second angle, the moving piece is moved to the second position, and the detector sends a second signal.

2. The structure of claim 1, wherein the moving piece comprises a first assembled sheet, the first assembled sheet comprises a main board and a bended board, the main board is parallel to the base board and is movably located on the base board, the main board and the detector are on respective opposite sides of the base board, the bended board is substantially perpendicular to the main board, the bended board is between the main board and the detector, the base board defines a sliding slot, the bended board extends through the sliding slot and is configured for triggering the detector to send the first signal or the second signal.

3. The structure of claim 2, wherein the base board comprises two limiting protrusions, the two limiting protrusions are arranged along the line, the main board defines two grooves, the two grooves extend along the line, the two limiting protrusions are slidably inserted in the two grooves, respectively, a width of each of the two grooves is equal to a width of each of the two limiting protrusions, the two limiting protrusions are configured for limiting the main board to move along the line.

4. The structure of claim 3, wherein each of the two limiting protrusions defines a threaded hole, the structure further comprises two first screws, each of the two first screws comprises a threaded portion and a screw head, the threaded portion of each first screw is inserted into the threaded hole of a corresponding limiting protrusion of the two limiting protrusions to attach the main board to the base board, a width of the screw head of each first screw is larger than the width of each groove, and a distance between the screw head of each first screw and the base board is equal to a thickness of the main board.

5. The structure of claim 2, wherein the moving piece further comprises a second assembled sheet, a third assembled sheet, and a first shaft, the second assembled sheet and the third assembled sheet are symmetrical to each other, the second assembled sheet comprises a first board and a second board, the third assembled sheet comprises a third board and a fourth board, the first board and the third board are located on the main board, the second board and fourth board are perpendicular to the base board, a first gap is formed between the second board and the fourth board, an end of the link rod is in the first gap, the first shaft extends through the second board, the link rod, and the fourth board, the link rod is rotatable around the first shaft.

6. The structure of claim 5, wherein the bracket comprises a flipping board, two fourth assembled sheets, and a second shaft, the flipping board is located on the base board and is rotatable around the axis, the two fourth assembled sheets are symmetrical to each other, and each of the two fourth assembled sheets comprises a fifth board and a sixth board, the fifth board is located on the flipping board, a second gap is formed between the sixth boards of the two fourth assembled sheets, an end of the link rod away from the first gap is in the second gap, the second shaft extends through the sixth boards and the link rod, the link rod is further rotatable around the second shaft.

7. The structure of claim 1 further comprises a reset component, the reset component comprises a first reset sheet, a second reset sheet, a reset shaft, and a spring, the first reset sheet is located on the bracket, the second reset sheet is located on the base board, the reset shaft extends along the axis and penetrates through the first reset sheet and the second reset sheet, the first reset sheet and the second reset sheet are rotatable around the reset shaft, the spring surrounds the reset shaft and is configured for pushing the bracket to rotate to the first angle.

8. The structure of claim 1, wherein the detector comprises a shell and a trigger, the trigger is movably located on the shell along the line, when the moving piece moves to the first position, the moving piece pushes the trigger towards the shell to retract the trigger into the shell, then the trigger triggers the first signal; when the moving piece moves to the second position, the moving piece moves away from the trigger and the trigger sticks out of the shell, then the trigger triggers the second signal.

9. A server comprising:
a chassis defining an opening;
a door panel rotatable relative to the chassis and configured for covering or uncovering the opening; and
a structure for detecting positions of the door panel, the structure comprising:
a base board;
a moving piece movable along a line between a first position and a second position on the base board;
a bracket rotatable around an axis between a first angle and a second angle on the base board, the axis substantially perpendicular to the line, and the bracket configured for supporting a door panel;
a link rod connected to the bracket and the moving piece; and
a detector positioned on the base board,
wherein the bracket rotates with the door panel to move the moving piece by the link rod, when the door panel closes the opening, the bracket is rotated to the first angle, the moving piece is moved to the first position, and the detector sends a first signal; when the door panel opens the opening, the bracket is rotated to the second angle, the moving piece is moved to the second position, and the detector sends a second signal.

10. The server of claim 9, wherein the moving piece comprises a first assembled sheet, the first assembled sheet comprises a main board and a bended board, the main board is parallel to the base board and is movably located on the base board, the main board and the detector are on two opposite sides of the base board, the bended board is substantially perpendicular to the main board, the bended board is between the main board and the detector, the base board defines a sliding slot, the bended board extends through the sliding slot and is configured for triggering the detector to send the first signal or the second signal.

11. The server of claim 10, wherein the base board comprises two limiting protrusions, the two limiting protrusions are arranged along the line, the main board defines two grooves, the two grooves extend along the line, each of the two limiting protrusions is slidably inserted in each of the two grooves, a width of each of the two grooves is equal to a width of each of the two limiting protrusions, the two limiting protrusions are configured for limiting the main board to move along the line.

12. The server of claim 11, wherein each of the two limiting protrusions defines a threaded hole, the structure further comprises two first screws, each of the two first screws comprises a threaded portion and a screw head, the threaded portion of each first screw is inserted into the threaded hole of a corresponding limiting protrusion of the two limiting protrusions to attach the main board to the base board, a width of the screw head of each first screw is larger than the width of each groove, and a distance between the screw head of each first screw and the base board is equal to a thickness of the main board.

13. The server of claim 10, wherein the moving piece further comprises a second assembled sheet, a third assembled sheet, and a first shaft, the second assembled sheet and the third assembled sheet are symmetrical to each other, the second assembled sheet comprises a first board and a second board, the third assembled sheet comprises a third board and a fourth board, the first board and the third board are located on the main board, the second board and fourth board are perpendicular to the base board, a first gap is formed between the second board and the fourth board, an end of the link rod is in the first gap, the first shaft extends through the second board, the link rod, and the fourth board, the link rod is rotatable around the first shaft.

14. The server of claim 13, wherein the bracket comprises a flipping board, two fourth assembled sheets, and a second shaft, the flipping board is located on the base board and is rotatable around the axis, the two fourth assembled sheets are symmetrical to each other, and each of the two fourth assembled sheets comprises a fifth board and a sixth board, the fifth board is located on the flipping board, a second gap is formed between the sixth boards of the two fourth assembled sheets, an end of the link rod away from the first gap is in the second gap, the second shaft extends through the sixth board and the link rod, the link rod is further rotatable around the second shaft.

15. The server of claim 9, wherein the structure further comprises a reset component, the reset component comprises a first reset sheet, a second reset sheet, a reset shaft, and a spring, the first reset sheet is located on the bracket, the second reset sheet is located on the base board, the reset shaft extends along the axis and penetrates through the first reset sheet and the second reset sheet, the first reset sheet and the second reset sheet are rotatable around the reset shaft, the spring surrounds the reset shaft and is configured for pushing the bracket to rotate to the first angle.

16. The server of claim 9, wherein the detector comprises a shell and a trigger, the trigger is movably located on the shell along the line, when the moving piece moves to the first position, the moving piece pushes the trigger towards the shell to retract the trigger into the shell, then the trigger triggers the first signal; when the moving piece moves to the second position, the moving piece moves away from the trigger and the trigger sticks out of the shell, then the trigger triggers the second signal.

17. A computing system comprising:
a rack; and
a plurality of servers placed in the rack, each of the plurality of servers comprising:
a chassis defining an opening;
a door panel rotatable relative to the chassis and the door panel configured for covering or uncovering the opening; and
a structure for detecting positions of the door panel, the structure comprising:
a base board;
a moving piece movable along a line between a first position and a second position on the base board;
a bracket rotatable around an axis between a first angle and a second angle on the base board, the axis substantially perpendicular to the line, and the bracket configured for supporting a door panel;
a link rod connected to the bracket and the moving piece; and
a detector positioned on the base board,
wherein the bracket rotates with the door panel to move the moving piece by the link rod, when the door panel closes the opening, the bracket is rotated to the first angle, the moving piece is moved to the first position, and the detector sends a first signal; when the door panel is opens the opening, the bracket is rotated to the second angle, the moving piece is moved to the second position, and the detector sends a second signal.

18. The computing system of claim 17, wherein the moving piece comprises a first assembled sheet, the first assembled sheet comprises a main board and a bended board, the main board is parallel to the base board and is movably located on the base board, the main board and the detector are on two opposite sides of the base board, the bended board is substantially perpendicular to the main board, the bended board is between the main board and the detector, the base board defines a sliding slot, the bended board extends through the sliding slot and is configured for triggering the detector to send the first signal or the second signal;
the base board comprises two limiting protrusions, the two limiting protrusions are arranged along the line, the main board defines two grooves, the two grooves extend along the line, each of the two limiting protrusions is slidably inserted in each of the two grooves, a width of each of the two grooves is equal to a width of each of the two limiting protrusions, the two limiting protrusions are configured for limiting the main board to move along the line;
each of the two limiting protrusions defines a threaded hole, the structure further comprises two first screws, each of the two first screws comprises a threaded portion and a screw head, the threaded portion of each first screw is inserted into the threaded hole of a corresponding limiting protrusion of the two limiting protrusions to attach the main board to the base board, a width of the screw head of each first screw is larger than the width of each groove, and a distance between the screw head of each first screw and the base board is equal to a thickness of the main board.

19. The computing system of claim 18, wherein the moving piece further comprises a second assembled sheet, a third assembled sheet, and a first shaft, the second assembled sheet and the third assembled sheet are symmetrical to each other, the second assembled sheet comprises a first board and a second board, the third assembled sheet comprises a third board and a fourth board, the first board and the third board are located on the main board, the second board and fourth board are perpendicular to the base board, a first gap is formed between the second board and the fourth board, an end of the link rod is in the first gap, the first shaft extends through the second board, the link rod, and the fourth board, the link rod is rotatable around the first shaft;
the bracket comprises a flipping board, two fourth assembled sheets, and a second shaft, the flipping board is located on the base board and is rotatable around the axis, the two fourth assembled sheets are symmetrical to each other, and each of the two fourth assembled sheets comprises a fifth board and a sixth board, the fifth board is located on the flipping board, a second gap is formed between the sixth boards of the two fourth assembled sheets, an end of the link rod away from the first gap is in the second gap, the second shaft extends through the sixth boards and the link rod, the link rod is further rotatable around the second shaft.

20. The computing system of claim 17, wherein the structure further comprises a reset component, the reset component comprises a first reset sheet, a second reset sheet, a reset shaft, and a spring, the first reset sheet is located on the bracket, the second reset sheet is located on the base board, the reset shaft extends along the axis and penetrates through the first reset sheet and the second reset sheet, the first reset sheet and the second reset sheet are rotatable around the reset shaft, the spring surrounds the reset shaft and is configured for pushing the bracket to rotate to the first angle;
the detector comprises a shell and a trigger, the trigger is movably located on the shell along the line, when the moving piece moves to the first position, the moving piece pushes the trigger towards the shell to retract the trigger into the shell, then the trigger triggers the first signal; when the moving piece moves to the second position, the moving piece moves away from the trigger and the trigger sticks out of the shell, then the trigger triggers the second signal.
